(19) United States
(12) Patent Application Publication
(10) Pub. No.: US 2011/0050218 A1
(43) Pub. Date: Mar. 3, 2011

(54) NON-CONTACT MAGNETIC CURRENT SENSING AND DISTRIBUTION SYSTEM FOR DETERMINING INDIVIDUAL POWER READINGS FROM A PLURALITY OF POWER SOURCES

(76) Inventor: Kurt L. Lohss, Pentwater, MI (US)

(21) Appl. No.: 12/868,387

(22) Filed: Aug. 25, 2010

Related U.S. Application Data
(60) Provisional application No. 61/275,322, filed on Aug. 28, 2009.

(51) Int. Cl. G01R 33/06

(52) U.S. Cl. 324/251

(57) ABSTRACT

A non-contact magnetic current sensing system (100) for measuring a plurality of power generation sources includes one or more fused electrical inputs (104, 105) that are arranged in parallel manner to form a comb feeding a center conductor member for receiving power from the power generation sources. A return connection block (113) is separated from the plurality of input fuses for providing a return path for the power generation sources. An electronic current sensing module (300) is used for providing current sensing for each of the plurality of input fuses (104, 105) in a non-contact manner. The invention provides that the electronic current sensing module is positioned over the comb for electrically connecting the electric current module to each of the plurality of input fuses and is powered solely from the power generation sources without the use of power from electrical mains.

### CROSS REFERENCE TO RELATED APPLICATIONS

This application claims priority under 35 U.S.C. §120 to U.S. Provisional Application Ser. No. 61/275,322, entitled “System and Method for Non-Contact Magnetic Current Sensing, Calibration, Telemetry and Distribution of Individual Power Readings from Singular or Multiple Electrical Generation Circuits” filed on Aug. 25, 2009 and owned by Amptech, Inc.

### FIELD OF THE INVENTION

The present invention relates generally to electrical measurement and more particularly to a non-contact magnetic current sensing and power monitoring system for measuring power readings from individual power sources.

### BACKGROUND OF THE INVENTION

Various systems for monitoring power monitoring and providing electrical distribution are known in the electrical power arts. In many power applications, a distribution board or panel board is a component used in an electrical supply system that divides an electrical power feed into subsidiary circuits. A protective fuse or circuit breaker is often used for each circuit that is contained in a common enclosure. In some cases, a main switch or residual-current device (RCD) can also be incorporated in the system for controlling over voltages and currents.

In power applications, conventional methods of sensing current often uses a series dropping resistor where a voltage is measured across the resistance and used in combination with ohm's law to determine current flow. One drawback of this approach is that it requires physical connection to determine current. Moreover, some nominal power loss also occurs due to the resistance placed in series with the circuit. Still other more sophisticated methods use magnetic Hall current sensing that requires that a current sensed wire be placed inside a magnetic sensor core. This type of physical connection is difficult to install and service making it undesirable for field applications.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is a top view illustrating the layout of components used in connection with an embodiment of the present invention.

FIG. 2 is a top view illustrating the electrical current flow direction of the components used in an embodiment of the present invention.

FIG. 3 is a top view illustrating the printed circuit board outline illustrating sensor position of the current invention.

FIG. 4 is a block diagram illustrating a wireless system configuration using the non-contact magnetic current sensing and distribution system according to another embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE PREFERRED EMBODIMENT

Before describing in detail embodiments that are in accordance with the present invention, it should be observed that the embodiments reside primarily in combinations of method steps and apparatus components related to a non-contact magnetic current sensing and distribution system. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of a non-contact magnetic current and distribution system described herein. The non-processor circuits may include, but are not limited to, a radio receiver, a radio transmitter, signal drivers, clock circuits, power source circuits, and user input devices. As such, these functions may be interpreted as steps of a method to perform a non-contact magnetic current and distribution system. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

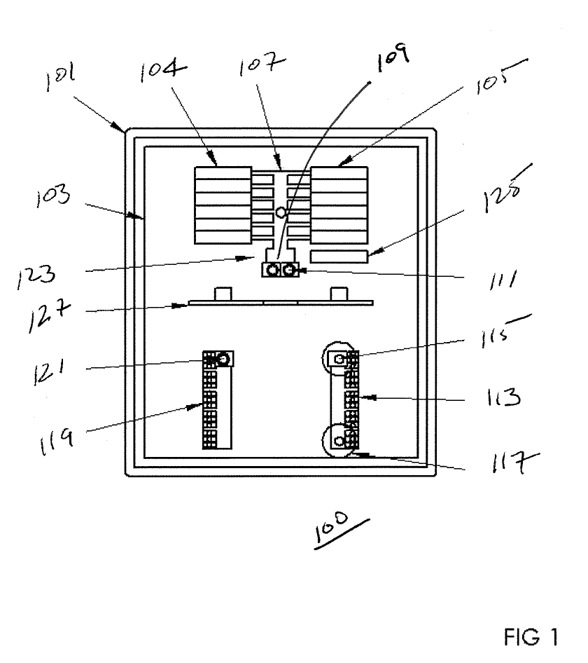

FIG. 1 is a top view illustrating the position and layout of components used in connection with the non-contact magnetic current sensing and distribution system according to an embodiment of the present invention. The system 100 includes an outer waterproof enclosure 101 where an inner panel 103 is fastened to an inside perimeter of the waterproof enclosure 101. This arrangement allows the inner panel 103 to be easily separated from the waterproof enclosure 101 if replacement or service is needed without removing the waterproof enclosure 101 from a wall or other rigid structure. A plurality of multiple electrical inputs each include a plurality of input fuse holders 104,105 that are positioned in two parallel columns at a top section of the inner panel 103. These holders 104, 105 are connected to power generation sources such as solar cells, batteries, generators or other power generating devices and are arranged in a manner so that they resemble teeth in a hair comb. This arrangement of input power input strings connect to fuse holders 104, 105 that work to form a conductive bank or “comb” 107. The electrical comb 107 includes a center conductive member 109 that is used as an electrical bus for connecting to other electrical circuits at its lower end. Thus, the comb 107 electrically connects to each fuse holder 104, 105 to a single output lug 111 located at the lower portion of the center conductive member 109. Further, located in a lower portion of the inner panel 103, a return connection block 113 includes an output lug 115 and is used for providing a return circuit connection. An electrical isolator 117 is also mounted to the connection block 113 for both electrically insulating and isolating the return connection block 113 from inner panel 103.

Located adjacent to the return connection block 113, a ground connection block 119 is used for providing an earth ground through ground lug 121 to the inner panel 103 and electrical components therein. An insulator 127 provides isolation as well as a physical barrier between the comb 107, the electrical isolator 117 and ground connection block 119. An insulator 127 also operates to minimize inadvertent contact between the single output lug 111, output log 115 and ground lug 121. As described herein, an electronic module 123 is powered solely from the power sources and connects with the single conductive comb 107 for measuring each individual circuit current, the string voltage, ambient temperature and humidity. This data can then be transmitted to a web-enabled coordinator and/or computer system for processing and subsequent analysis. Further, a module fuse located in fuse holder 125 protects the electronic module 123 from current overload.

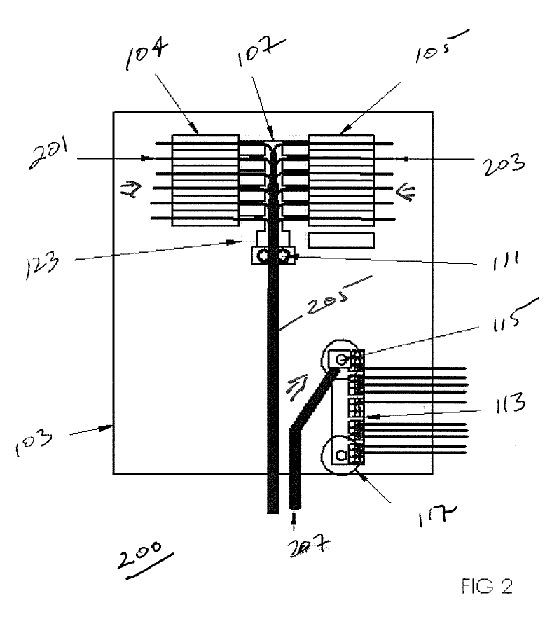

FIG. 2 is diagram illustrating the direction of electrical current flow for the components as shown in FIG. 1. The current flow diagram 200 shows a first input current path 201 and second input current path 203 that enter each fuse holder 104, 105 respectively. The wired connection enters a electrical fuse (not shown) located in each fuse holder 104, 105 and exits the fuse holder 104, 105 into the comb 107. All single current generation inputs are combined into a single high current conductor 205 that carries the sum of each individual currents at output lug 123. As will be evident to those skilled in the art, the comb geometry consists of parallel current paths 201, 203 for each fused input circuit. Each single current path 201, 203 produces a magnetic field perpendicular to the current path. The total magnetic field strength is directly proportional to the amount of current flowing in each of the input conductors.

As described herein, an electronic module (not shown) using one or more Hall sensing devices (not shown) is used for accurately measuring each of the individual magnetic fields produced by the current flowing through each input conductor. In use, the electronic module can be powered solely from the power generation sources without the use of power from electrical mains. The Hall sensing devices are proximity devices and are located adjacent to the input conductors without the need for each conductor to pass through a current sensor or making a direct electrical connection. Thus, these non-contact current measurements can be more easily determined yet still allowing the module to be removed for later replacement or servicing. The current return path 207 uses a conventional multiple connection block 113 with an integrated high current lug 115 that is electrically isolated from the inner panel 103. In use, the earth ground path also includes a conventional multiple connection block 119 with an integrated high current lug 121 that is electrically connected to the inner panel 103 and an earth ground (not shown).

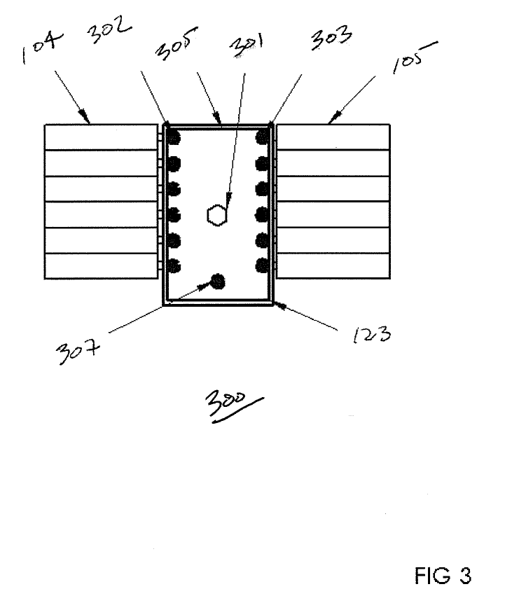

FIG. 3 is a top view of the printed circuit board illustrating the configuration of the sensor module used in FIG. 1. The printed circuit board 300 uses the electronic module 123 that is mechanically fastened to the topside of the comb 107 with fastener 301. Multiple Hall sensing elements 302, 303 are proximity devices that are positioned adjacent to the current carrying conductive circuits. Printed circuit board 305 is used with the Hall sensing elements 302, 303 so that the printed circuit board 305 electrically connects Hall sensing elements 302, 303 to other electronic elements such as a microprocessor, transceiver and/or power supply components (not shown). One Hall sensor 307 may also be configured to measure the total current through the output lug 111 as shown in FIG. 1. The entire circuit can then be hermetically sealed for protecting the electronic module 123 from harsh weather conditions or airborne contaminants.

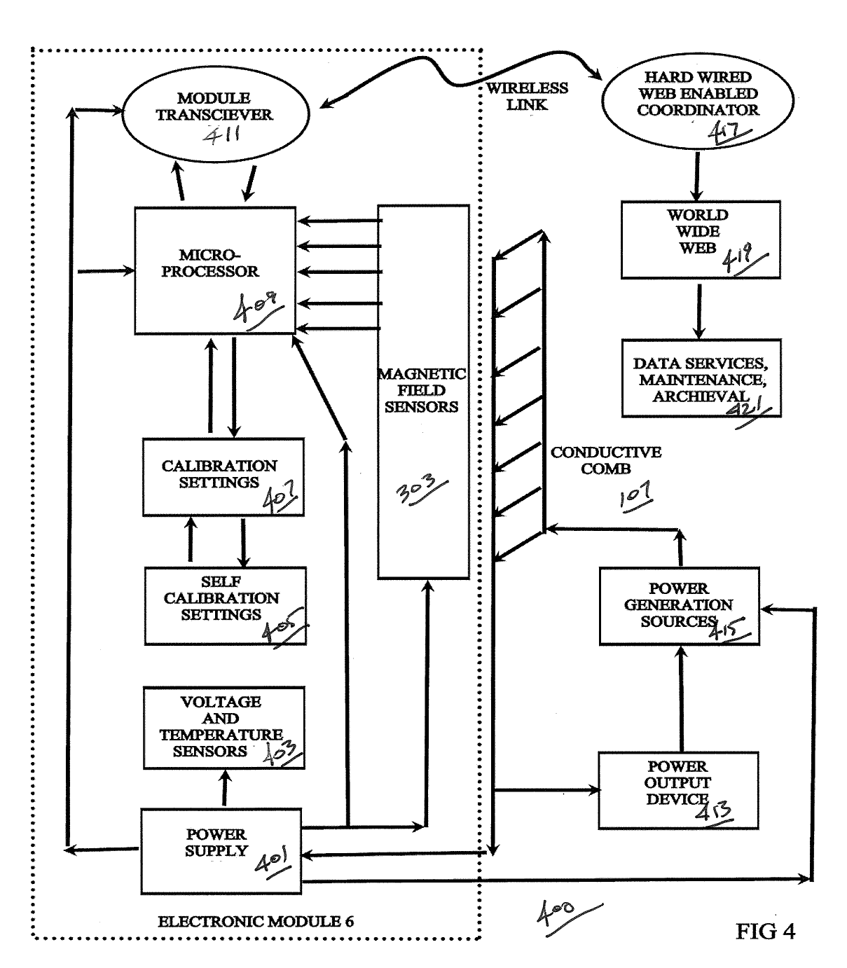

Finally, FIG. 4 is a block diagram illustrating a wireless communications system configured using the non-contact magnetic current sensing and distribution system as shown in FIGS. 1-3. The wireless system configuration 400 utilizes a microprocessor 409 along with control software for determining the magnetic from each of the magnetic field sensors 303. Thus the current information from the individual power generation sources 415 that is supplied through the conductive comb 107 can be readily conveyed for analysis using a wireless transceiver 411. Moreover, simplified field calibration can more easily be performed using this data without the use of the additional field instrumentation.

In operation, a power supply 401 efficiently converts a small portion of the unregulated power from the fuse inputs on the conductive comb 107 to a regulated voltage capable of powering the voltage and temperature sensors 403 as well as other electronics in the non-contact magnetic current sensing and distribution system 100. A wireless transceiver 411 provides a radio frequency (RF) wireless link for providing two-way RF data communication from the electronic module 123 via the wireless link to a web enabled remote coordinator 417. The microprocessor 409 monitors the transceiver 411 and receives data from the magnetic sensors 303. The microprocessor 409 provides functions such as applying calibration settings 407, calculating current readings from the magnetic sensors 303 and measuring string voltage for each power generation source. Also, the microprocessor can also determine the temperature of the sensor module as well as temperature sensors 403 and can transmit these values to a web based coordinator 417 via the transceiver 411. Optionally, the software can also facilitate a simplified push button field calibration 405 without the use of additional instrumentation. The web enabled coordinator 417 can send a data request code to one or more of the transceiver modules for interrogating its operational status. Upon receipt of a valid request, the microprocessor 409 measures individual sensor current, string voltage of the power sources from the conductive comb 107 and the module temperature and transmits this data back to coordinator 417 for global retrieval of information and data over the Internet and/or world wide web 419. Multiple modules may be accessed with all data being capable of being stored or archived 421 for future use.

Thus, the present invention is a system to monitor and report via telemetry single or multiple electrical current and voltage readings flowing from a source to a load. This invention is especially suited, but not limited to alternative energy measurement, metrology and management. This invention embodies an electrical distribution box employing non-contact current measurement of multiple circuits with wireless two way data telemetry link to a web enabled coordinator. Multiple electronic modules can be accessed with all data available from each to the coordinator.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

We claim:

1. A non-contact magnetic current sensing system for measuring a plurality of power generation sources comprising:
a plurality of electrical inputs from the power generation sources arranged in parallel to form a comb feeding a center conductor member;
a return connection block separated from the plurality of inputs for providing a return path for the power generation sources;
a electronic current sensing module for providing current sensing for each of the plurality of input fuses in a non-contact manner; and
wherein the electronic current sensing module is positioned over the comb for electrically connecting the electric current module to each of the plurality of electrical inputs.

2. A non-contact magnetic current sensing system as in claim 1, further comprising:
a grounding connection block for providing an earth ground for the non-contact magnetic current sensing system.

3. A non-contact magnetic current sensing system as in claim 1, further comprising:
an insulator barrier positioned between the plurality of input fuses and the return connection block.

4. A non-contact magnetic current sensing system as in claim 1, wherein the electronic current sensing module includes a plurality of Hall effect devices for measuring current.

5. A non-contact magnetic current sensing system as in claim 1, wherein the electronic current sensing module is powered by the power generation sources.

6. A non-contact magnetic current sensing system as in claim 3, wherein the electronic current sensing module is not power by an electrical mains input.

7. A non-contact magnetic current sensing system as in claim 1, wherein the power generation sources are solar cells.

8. A non-contact magnetic current sensing system as in claim 1, wherein the comb is mounted within a sealed electrical box.

9. A non-contact magnetic current sensing system for measuring a plurality of power generation sources comprising:
a plurality of parallel arranged electrical inputs forming a comb having a center conductor for providing an input current path for the plurality of current sources;
a return connection block for providing a return current path for the plurality of power sources; and
an electronic current sensing module for mounting over the comb for providing a plurality of Hall effect devices to measure current for each one of the plurality of current sources.

10. A non-contact magnetic current sensing system as in claim 9, wherein the Hall effect devices make no physical contact with the plurality of current sources.

11. A non-contact magnetic current sensing system as in claim 9, wherein the electronic current sensing module is powered solely by the power generation sources.

12. A non-contact magnet current sensing system as in claim 9, wherein the electronic current sensing module is not powered by an input power main.

13. A non-contact magnet current sensing system as in claim 9, further comprising a grounding connection block for providing an earth ground for the non-contact magnetic current sensing system.

14. A non-contact magnetic current sensing system as in claim 9, further comprising an insulator barrier positioned between the plurality of input fuses and the return connection block.

15. A non-contact magnetic current sensing system as in claim 9, wherein the system is mounted in a sealed electrical box.

16. A non-contact magnetic current sensing system as in claim 9, wherein the electrical inputs are fused.

17. A non-contact magnetic current sensing system as in claim 9, wherein the plurality of power generation sources are solar cells.

18. A system from non-contact magnetic current sensing system for measuring a plurality of solar cell power sources comprising:
a plurality of fused electrical inputs arranged in parallel to form a comb feeding a center conductor member for receiving power from the solar cell power sources;
a return connection block separated from the plurality of fused electrical inputs for providing a return path for the solar cell power sources;
a grounding connection block for providing an earth ground for the non-contact magnetic current sensing system;
an insulator barrier positioned between the plurality of fused electrical inputs and the return connection block;
a electronic current sensing module for providing current sensing for each of the plurality of input fuses in a non-contact manner; and
wherein the electronic current sensing module is powered solely by the power generation sources.

19. A non-contact magnetic current sensing system as in claim 18, wherein the electronic current sensing module is positioned over the comb for electrically connecting the electronic current module to each of the plurality of fused inputs.

20. A non-contact magnetic current sensing system as in claim 18, wherein the electronic current sensing module includes a plurality of Hall effect devices for measuring current.

21. A non-contact magnetic current sensing system as in claim 20, wherein the electronic current sensing module is not powered by an electrical mains input.

22. A non-contact magnetic current sensing system as in claim 18, further comprising a sealed electrical box for housing the non-contact magnetic current sensing system.
